(19) United States
(12) Patent Application Publication
(10) Pub. No.: US 2020/0230607 A1
(43) Pub. Date: Jul. 23, 2020

(54) TEMPERATURE CONTROL DEVICE AND NUCLEIC ACID AMPLIFICATION APPARATUS

(71) Applicant: HITACHI, LTD., Tokyo (JP)

(72) Inventors: Tatsuya KOBARI, Tokyo (JP); Wataru SATO, Tokyo (JP)

(73) Assignee: HITACHI, LTD., Tokyo (JP)

(21) Appl. No.: 16/487,005

(22) PCT Filed: Nov. 6, 2017
(86) PCT No.: PCT/JP2017/039962

§ 371 Date: Aug. 19, 2019

(30) Foreign Application Priority Data
Feb. 20, 2017 (JP) 2017-028589

(51) Int. Cl. B01L 7/00; H01L 35/30

(52) U.S. Cl. CPC B01L 7/52; B01L 2300/0609; B01L 2300/025; H01L 35/30

(57) ABSTRACT

A temperature control device has: a sample container holder that holds a sample container; multiple temperature sensors that measure the temperature near a sample; a temperature control element that heats or cools the sample container holder; a storage unit that stores a mathematical model; and a computation unit that analyzes the mathematical model based on the sensors. The mathematical model serves as a thermal network model in which nodes and a thermal resistance between predetermined nodes are set, the nodes corresponding at least to the sample, sample container, sample container holder, sensors, and temperature control element. Each node has a predetermined heat capacity, and the computation unit uses a state estimation algorithm to calculate a thermal resistance estimated value between the sample container and the sample container holder and a temperature estimated value of the sample, based on the output from each of the sensors and the thermal network model.

### TECHNICAL FIELD

The present invention relates to a temperature control device that controls the temperature of a sample to a predetermined temperature and a nucleic acid amplification apparatus including the temperature control device.

### BACKGROUND ART

A temperature control device, mainly, employs a temperature sensor to measure the temperature of a subject to be temperature-controlled, and determines, on the basis of the resulting information, an output to a temperature control element such as a heater or a Peltier element to supply the output thereto. Thus, the precise and accurate temperature information of the subject has a great influence on the reliability of the temperature control device. Furthermore, the transfer of heat from the temperature control element to the subject, for example, the thermal resistance from the temperature control element to the subject also has a great influence on the reliability.

Background art related to conventional temperature control devices includes PTL 1 and PTL 2.

PTL 1 discloses a method, in which in order to subject an amplification solution containing target nucleic acids to be amplified and components necessary for amplification, to nucleic acid amplification treatment, a temperature measuring element provided with a reaction container measures the temperature of the reaction container, and on the basis of the measured temperature, the temperature of the reaction container is regulated.

PTL 2 discloses a method including means of measuring the temperature of a dummy substance by using a measurement container, the measurement container being prepared for a test container containing a test solution to be subjected to nucleic acid amplification treatment, the measuring container containing the dummy substance equal in heat conductivity and heat capacity to the test solution, the measuring container having the same shape and thermal conductivity as those of the test container. The test solution can be temperature-controlled through estimation in the temperature transition of the test solution, with performance of temperature regulation for the measurement container while measuring the temperature of the dummy substance to obtain a suitable control voltage and following performance of temperature regulation for the test container.

### CITATION LIST

### Patent Literature

PTL 1: JP 2012-100582 A

PTL 2: JP 2014-32153 A

### SUMMARY OF INVENTION

### Technical Problem

In the method disclosed in PTL 1, although the temperature of the reaction container and the temperature correction value thereof are obtained, the temperature of the amplification solution is not determined. Thus, the method has a disadvantage in that it is unknown what type of temperature cycle amplification solution as a sample has experienced.

In the method disclosed in PTL 2, the contact thermal resistance between the test container or the measurement container, and a container setting portion in which such a container is set is different every time the is set, so that it is difficult to obtain reproducibility of the contact state. Thus, the method has a disadvantage in that no information on the transfer of heat from a heating element that heats the test solution to the test solution.

A temperature control device can be applied to a nucleic acid amplification apparatus to be installed in genetic testing equipment, for example. In particular, a nucleic acid amplification apparatus using a nucleic acid polymerase chain reaction (PCR), repeats suitable temperature control on a reaction solution in the range of about 45° C. to 95° C., to amplify nucleic acids. Requirement of rapid amplification of nucleic acids for such genetic testing equipment creates a need for highly-reliable temperature control on the reaction solution.

For the temperature control device, imprecise information on the temperature of a subject and the transfer of heat through a heat transfer path results in a disadvantage such as overshoot, variation, or dispersion of the temperature of the subject, time expense to reach a target temperature, or remaining offset to the target temperature. Thus, such a disadvantage lowers the reliability of the temperature control device. Meanwhile, the nucleic acid amplification apparatus is difficult to directly measure the temperature of a subject, and includes contact thermal resistance on a heat transfer path. Thus, there arises an issue in difficulty in obtaining precise information.

Specifically, for the nucleic acid amplification apparatus, contamination is disallowable for the reaction solution to be temperature-controlled due to containing a vivo-derived sample. In addition, several tens to several hundreds microliters of the reaction solution is supplied to one reaction container, whereby the reaction solution is small in heat capacity and is sensitive to heat loss. Therefore, temperature information on the reaction solution is difficult to be obtained with a method such as direct insertion of a thermocouple into the reaction solution. Furthermore, the reaction container containing the reaction solution is subjected to nucleic acid amplification treatment in a state where the reaction container is disposed in a reaction container holder, thereby imparting the contact thermal resistance between the reaction container and the reaction container holder, the contact thermal resistance being different for each treatment.

### Solution to Problem

A temperature control device includes: a sample container holder configured to hold a sample container; a plurality of temperature sensors configured to measure a temperature near a sample contained in the sample container; a temperature control element configured to heat or cool the sample container holder; a storage unit configured to store a mathematical model; and a computation unit configured to analyze the mathematical model, based on an output from each of the plurality of temperature sensors, in which the mathematical model serves as a thermal network model in which nodes and a thermal resistance between predetermined nodes are set, the nodes corresponding at least to the sample, the sample container, the sample container holder, the plurality of temperature sensors, and the temperature control element, each node having a predetermined heat capacity, and the computation unit uses a state estimation algorithm to calculate a thermal resistance estimated value between the sample container and the sample container holder and a temperature estimated value of the sample, based on the output from each of the plurality of temperature sensors and the thermal network model.

### Advantageous Effects of Invention

There is provided a highly-reliable temperature control device that quantitatively evaluates the contact thermal resistance between a reaction container and a reaction container holder, the contact thermal resistance being different for each treatment, and the temperature of a sample, with a different physical quantity measurable of the contact thermal resistance and the temperature of the sample.

### BRIEF DESCRIPTION OF DRAWINGS

FIG. 1 is an illustration of the configuration of a temperature control device according to a first embodiment.

FIG. 2 is a diagram of an exemplary thermal network model.

FIG. 3 is a diagram of an exemplary thermal network model.

FIG. 4 is a diagram of the configuration of a nucleic acid amplification apparatus of a second embodiment.

### DESCRIPTION OF EMBODIMENTS

### First Embodiment

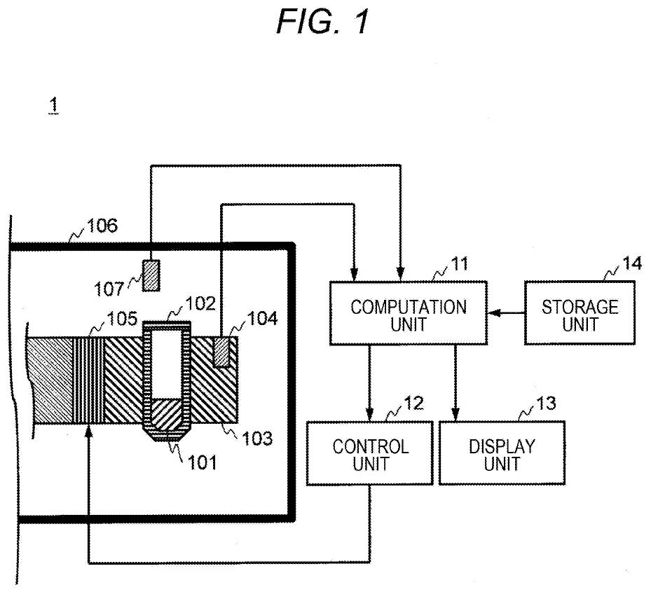

FIG. 1 is an illustration of the configuration of a temperature control device 1 according to a first embodiment. The temperature control device 1 has: a sample container holder 103 that holds the sample container 102 containing a sample 101; temperature sensors 104 and 107; and a temperature control element 105; and a casing 106, and includes an computation unit 11; a control unit 12; a display unit 13; and a storage unit 14.

The sample container holder 103 is disposed in the casing 106 and has a shape capable of holding the sample container 102. In addition, for smoothly conducting heat exchange with the sample container 102, it is desirable for the sample container holder 103 to be fabricated from a material having high heat conductivity, such as copper or aluminum, to be sufficiently small in heat capacity to the amount of heat to be input, and to have a sufficiently large heat transfer area between the sample container holder 103 and the sample container 102.

The holder temperature sensor 104 is provided along the sample container holder 103 to measure the temperature thereof, and the temperature measurement result is supplied to the computation unit 11, as a temperature near the sample 101. The in-casing temperature sensor 107 is provided in the casing and measures the temperature of an in-casing air, and the temperature measurement result is also supplied to the computation unit 11, as a temperature near the sample 101.

The storage unit 14 stores a mathematical model. The mathematical model is analytically modelized the thermal state of the temperature control device 1. For example, analysis of the thermal state of a system with a thermal network method uses a thermal network model that expresses the system by, for example, nodes, thermal resistance, or heat capacity.

The thermal network model stored in the storage unit 14 is supplied to the computation unit 11 and a measurement result related to the thermal state of the system is supplied to the computation unit 11, the measurement result being necessary for analysis of the thermal state of the system in accordance with the thermal network model. The temperature measurement results of the temperature sensors 104 and 107 are examples of the measurement result; however, the present invention is not limited to such examples. The analysis result of the thermal state of the system by the computation unit 11 is supplied to the control unit 12, and the control unit 12 controls the temperature control element 105 on the basis of the estimated temperature of the sample 101. In addition, the analysis result of the thermal state of the system by the computation unit 11 is supplied to the display unit 13, and the display unit 13 displays the analysis result or a cautionary notice based on the analysis result.

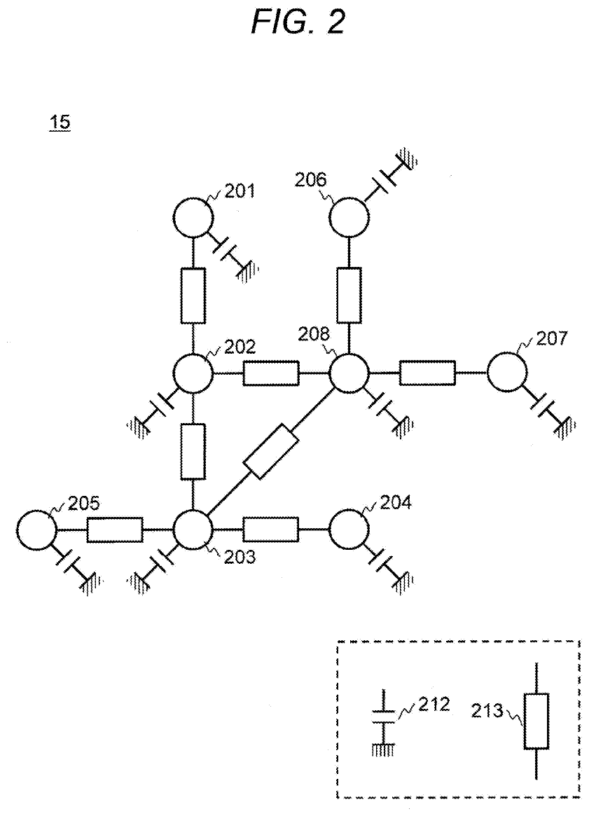

FIG. 2 is a diagram of a thermal network model (mathematical model) 15 stored in the storage unit 14. The thermal network model 15 considers: a sample node 201; a sample container node 202; a sample container holder node 203; a holder temperature sensor node 204; a temperature control element node 205; a casing node 206; an in-casing temperature sensor node 207 as nodes respectively corresponding to: the sample 101; the sample container 102; the sample container holder 103; holder temperature sensor 104; the temperature control element 105; the casing 106; and the in-casing temperature sensor 107. Furthermore, the thermal network model 15 considers an in-casing air node 208 as a node corresponding the in-casing air. A heat capacity 212 is set for each node. In addition, as heat transfer paths considering respective thermal resistances 213, there are considered between the sample node 201 and the sample container node 202, between the sample container node 202 and the sample container holder node 203, between the sample container node 202 and the in-casing air node 208, between the sample container holder node 203 and the temperature control element node 205, between the sample container holder node 203 and the in-casing air node 208, between the casing node 206 and the in-casing air node 208, between the sample container holder node 203 and the holder temperature sensor node 204, and between the in-casing air node 208 and the in-casing temperature sensor node 207. The thermal network model 15 may be a more detailed model in order to enable highly precise state estimation.

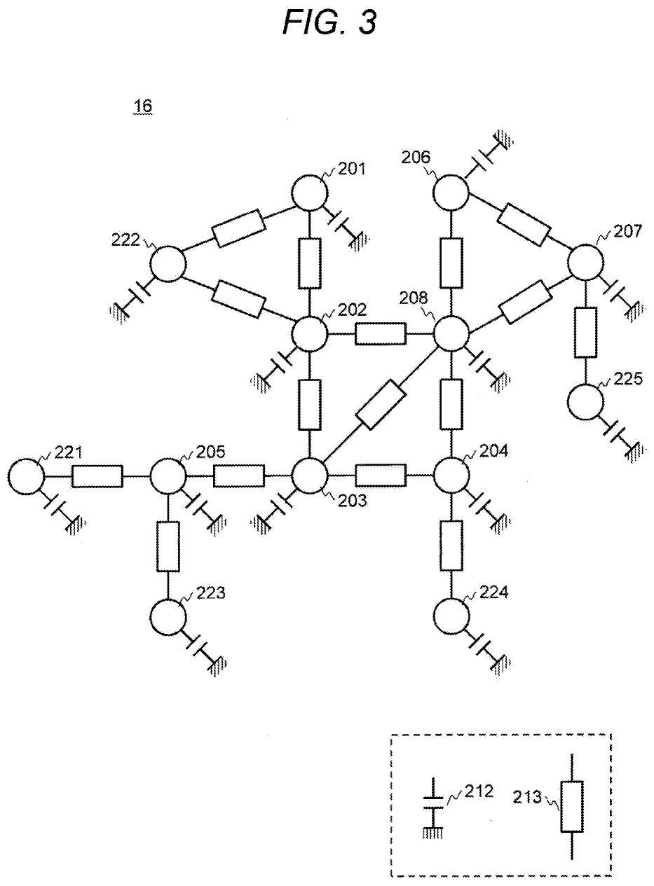

FIG. 3 is a diagram of the configuration of a thermal network model 16 that is a more detailed exemplary thermal network model. In addition to the thermal network model 15, the thermal network model 16 considers nodes respectively corresponding to: a nucleic acid amplification apparatus main body (hereinafter referred to as “apparatus main body”), an in-sample-container air; a temperature control element lead wire; a holder temperature sensor lead wire; and an in-casing temperature sensor lead wire, the nodes including: an apparatus main body node 221; an in-sample-container air node 222; a temperature control element lead wire node 223; a holder temperature sensor lead wire node 224; and an in-casing temperature sensor lead wire node 225. Similarly to the thermal network model 15, a heat capacity 212 is set for each node. Furthermore, in addition to heat transfer paths in thermal network model 15, as heat transfer paths considering respective thermal resistances 213, there are considered between a sample node 201 and the in-sample-container air node 222, between a sample container node 202 and the in-sample-container air node 222, between a holder temperature sensor node 204 and an in-casing air node 208, between a temperature control element node 205 and the apparatus main body node 221, between the temperature control element node 205 and the temperature control element lead wire node 223, between the holder temperature sensor node 204 and the holder temperature sensor lead wire node 224, an in-casing temperature sensor node 207 and a casing node 206, and between the in-casing temperature sensor node 207 and the in-casing temperature sensor lead wire node 225. Furthermore, in order to enable highly precise state estimation, for example, a temperature sensor may be disposed at the apparatus main body or the casing as necessary to increase actual measurement values, and a thermal network model may be adopted accordingly.

A temperature measurement result from a temperature sensor that measures the thermal state of a system and a thermal network model are supplied to the computation unit 11. A case where the thermal network model 15 is supplied to the computation unit 11 will be described as an example. The thermal resistance of each heat transfer path in the thermal network model 15 may be given as a direct problem from, for example, dimensions, thermophysical properties of materials, or empirical formulas, or may be obtained experimentally in advance. However, the thermal resistance between the sample container 102 and the sample container holder 103 (thermal resistance between the sample container node 202 and the sample container holder node 203) is different every time the sample container 102 is disposed, thereby making it difficult to obtain a precise thermal resistance value. Thus, the computation unit 11 computes with the temperature measurement result as an input, a state estimation algorithm that estimates a physical quantity difficult to measure, on the basis of the thermal network model 15. Here, the physical quantity difficult to measure indicates the thermal resistance between the sample container 102 and the sample container holder 103. This computation gives each of the nodal temperature, the thermal resistance and the heat transfer rate between the nodes. Examples of the state estimation algorithm that can be used include a Kalman filter, an extended Kalman filter, an unscented Kalman filter, an ensemble Kalman filter, and a particle filter. For the thermal network model 15, such a state estimation algorithm is used to perform analysis, with the temperature of the casing 106 large in heat capacity set as a constant value, the temperature of the sample container holder 103 and the temperature of the air in the casing 106 set as measured values, respectively, and the two variables of the temperature of the sample 101 and the thermal resistance between the sample container 102 and the sample container holder 103 set as unknown variables. This analysis allows obtaining the temperature of the sample 101 and the thermal resistance between the sample container 102 and the sample container holder 103 difficult to measure, and supplying the resulting values to the control unit 12. As a result, these numerical values can be reflected for the operation of the temperature control device 1.

The control unit 12 controls a value of current to be supplied to the temperature control element 105 in order to allow the sample 101 to experience a predetermined temperature transition. For example, on the basis of the temperature of the sample 101 obtained by the computation unit 11, the control unit 12 controls a value of current to be supplied to the temperature control element 105 in order to allow the sample 101 to experience a predetermined temperature transition.

The temperature control element 105 generates a heat transfer rate to the sample container holder 103, on the basis of the current supplied to the temperature control element 105. At this time, as long as only an exothermic reaction is required, a heating element such as a rubber heater is used. Alternatively, as long as an exothermic reaction and an endothermic reaction are required, a thermoelectric element such as a Peltier element is used. The temperature control element 105 is required at least to exert sufficient heat transfer to the sample 101. A plurality of temperature control elements 105 may be provided, or a temperature control element 105 may be disposed surrounding the sample container holder 103.

The display unit 13 displays a cautionary notice that suitable temperature control on the sample 101 is difficult, in a case where the analysis result of the computation unit 11 is significantly different from a desired temperature transition. For example, in a case where the thermal resistance between the sample container 102 and the sample container holder 103 obtained by the computation unit 11 is larger than a predetermined value, the amount of heat input by the temperature control element 105 insufficiently transfers to the sample 101. Thus, it is determined that an abnormality is present in the disposition of the sample container 102 to the sample container holder 103, and the display unit 13 displays a cautionary notice that suitable temperature control on the sample 101 is difficult. As supplementary information on the details of the cautionary notice, for example, the display unit 13 may display the numerical value of the analyzed thermal resistance. Alternatively, the display unit 13 may display a prediction result of time required for the sample 101 in order to experience a desired temperature transition, on the assumption that the temperature control is continued on the basis of the analyzed thermal resistance of the computation unit 11 and the rated performance of the temperature control element 105.

As described above, the physical quantity difficult to measure in the system of the temperature control device i is quantitatively evaluated with the different measurable physical quantity, whereby there can be provided the highly-reliable temperature control device 1.

### Second Embodiment

A nucleic acid amplification apparatus including the temperature control device 1 of the first embodiment will be described as a second embodiment. In the second embodiment, the casing, the sample container holder, the temperature sensors, and the temperature control element included in the temperature control device are collectively referred to as a temperature control unit. A nucleic acid amplification apparatus 2 including a plurality of temperature control units that holds a sample container containing a sample in each temperature control unit and has a mathematical model corresponding to each temperature control unit, thereby allowing a different temperature control at each temperature control unit.

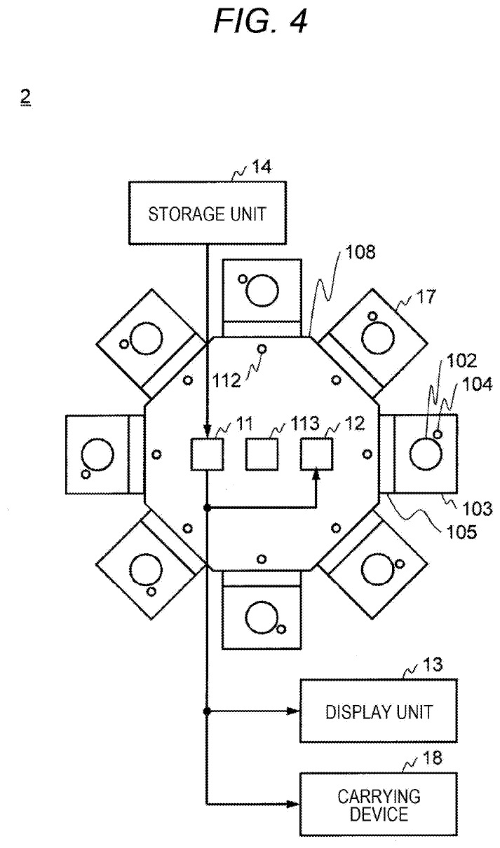

FIG. 4 is a diagram of the configuration of the nucleic acid amplification apparatus 2 of the second embodiment. The nucleic acid amplification apparatus 2 has: a plurality of temperature control units 17, each temperature control unit 17 holding a sample container 102 containing a sample to perform control temperature control; a computation unit 11; a control unit 12; a display unit 13; a storage unit 14 that stores a mathematical model corresponding to each temperature control unit 17, the nucleic acid amplification apparatus 2 including: an apparatus main body 108; at least one temperature sensor 112; at least one temperature control element 113; and a carrying device 18. Note that, in FIG. 4, the casing and the in-casing temperature sensor provided for each temperature control unit 17 are omitted.

For the nucleic acid amplification apparatus 2, a sample 101 corresponds to a reaction solution causing a nucleic acid amplification reaction, and a sample container 102 corresponds to a reaction container containing the reaction solution. In a PCR method, a temperature control cycle is repeated in which, for example, the reaction solution is heated to about 94° C. and maintained for 30 seconds to 1 minute, rapidly cooled to about 55° C., and heated at about 72° C. and maintained for 1 to 2 minutes. As described above, although the temperature information of the reaction solution is unobtainable directly from the reaction solution, the nucleic acid amplification apparatus must precisely perform a temperature control cycle in a short period. For such a temperature control cycle in a short period, the contact thermal resistance between the sample container and the sample container holder, the contact thermal resistance being different for each treatment also has nonnegligible effect. Thus, there is required more precise estimation of the temperature information of the reaction solution. Therefore, the temperature control device of the first embodiment is applied to the temperature control unit 17.

The temperature control unit 17 has: a sample container holder 103 that holds the sample container 102 containing the sample 101; a holder temperature sensor 104; a temperature control element 105; a casing; and an in-casing temperature sensor, the casing and the in-casing temperature sensor being not illustrated. The plurality of temperature control units 17 is provided on the apparatus main body 108. FIG. 4 exemplifies eight temperature control units 17 provided on the side faces of the apparatus main body 108, respectively. For the plurality of temperature control units 17, a plurality of mathematical models (thermal network model) corresponding to each temperature control unit 17 and the temperature measurement results by the holder temperature sensor and the in-casing temperature sensor of each temperature control unit 17 are supplied to the computation unit 11.

The temperature measurement results by the temperature sensors and the thermal network models are supplied to the computation unit 11. Such as described in the first embodiment, the computation unit 11 computes with the temperature measurement results as an input, a state estimation algorithm that estimates a physical quantity difficult to measure, on the basis of the thermal network models. This computation gives each of the nodal temperature, the thermal resistance and the heat transfer rate between the nodes. Examples of the state estimation algorithm to be used include a Kalman filter, an extended Kalman filter, an unscented Kalman filter, an ensemble Kalman filter, and a particle filter. The analysis result of the computation unit 11 is supplied to the control unit 12, the display unit 13, and the carrying device 18. The computation unit 11 uses such a state estimation algorithm to perform analysis, with the two variables of the temperature of the sample 101 and the thermal resistance between sample container 102 and the sample container holder 103 as unknown variables. This analysis allows obtaining the temperature of the sample 101 and the thermal resistance between the sample container 102 and the sample container holder 103 difficult to measure. As a result, the resulting numerical values can be reflected for the operation of the temperature control device 1 The computation unit 11 performs the above operations for the plurality of temperature control units 17.

On the basis of the analysis result of the computation unit 11, the control unit 12 controls a value of current to be supplied to the temperature control element 105 in order to allow the sample 101 to experience a temperature transition required in the PCR method. For example, on the basis of the temperature of the sample 101 obtained by the computation unit 11, the control unit 12 controls a value of current to be supplied to the temperature control element 105 in order to allow the sample 101 to experience a predetermined temperature transition.

The display unit 13 displays a cautionary notice that suitable temperature control on the sample 101 is difficult, depending on the analysis result of the computation unit 11. For example, in a case where the thermal resistance between the sample container 102 and the sample container holder 103 obtained by the computation unit 11 is larger than a predetermined value, the amount of heat input by the temperature control element 105 insufficiently transfers to the sample 101. Thus, it is determined that an abnormality is present in the disposition of the sample container 102 to the sample container holder 103, and the display unit 13 displays a cautionary notice that suitable temperature control on the sample 101 is difficult. As supplementary information on the details of the cautionary notice, for example, the display unit 13 may display the numerical value of the thermal resistance. Alternatively, time required for the sample 101 in order to experience a desired temperature transition may be calculated and the display unit 13 may display the prediction result, assuming that a case where the temperature control is continued on the basis of the analysis result of the computation unit 11 and the rated performance of the temperature control element 105.

The plurality of temperature control units 17 is connected to the apparatus main body 108. It is desirable that the temperature of the apparatus main body 108 be equal to or higher than the temperature of the temperature control unit 17 such that the heat of the temperature control element 105 of the temperature control unit 17 effectively transfers to the sample. Therefore, the apparatus main body 108 is provided with a temperature sensor 112 that measures the temperature of the apparatus main body 108 and a temperature control element 113 that maintains the temperature of the apparatus main body 108 constant.

At least one temperature sensor 112 is provided to the apparatus main body 108. In the example of FIG. 4, the temperature sensor 112 is provided near the temperature control element 105 of each temperature control unit 17. The temperature measurement result of the temperature sensor 112 is to be used to maintain the temperature of the apparatus main body 108 constant. In addition, the temperature measurement result may be supplied to the computation unit 11 to be used for computation of the state estimation algorithm such as described in the first embodiment.

At least one temperature control element 113 is provided to the apparatus main body 108. In the example of FIG. 4, one temperature control element 113 is provided at the center of the apparatus main body 108. On the basis of the temperature measurement result of the temperature sensor 112, the temperature control element 113 generates heat and absorbs heat so as to maintain the temperature of the apparatus main body 108 constant. The temperature control element 113 may be a rubber heater or a Peltier element that generates heat or absorbs heat in accordance with a supplied current, or a constant temperature oven may be employed to maintain the temperature of the apparatus main body 108 constant.

The carrying device 18 operates to dispose the sample container 102 in the sample container holder 103 and operates to remove the sample container 102 from the sample container holder 103. The carrying device 18 re-disposes the sample container 102, on the basis of the analysis result of the computation unit 11. For example, in a case where the thermal resistance between the sample container 102 and the sample container holder 103 obtained by the computation unit 11 is larger than a predetermined value, the amount of heat input by the temperature control element 105 insufficiently transfers to the sample 101. Thus, it is determined that an abnormality is present in the disposition of the sample container 102 to the sample container holder 103, the temperature control is stopped. Then, the sample container 102 is gripped and lifted, and then re-disposed in the sample container holder 103.

With the above embodiment, the physical quantity difficult to measure in a system of the nucleic acid amplification apparatus 2 is quantitatively evaluated with the different measurable physical quantity, thereby allowing implementation of the best course for the transfer of heat. Thus, the highly-reliable nucleic acid amplification apparatus 2 can be provided.

### INDUSTRIAL APPLICABILITY

Such a temperature device is applicable to heat control for a system difficult to measure the temperature of a sample with a temperature sensor, or for temperature control of a system having a variation in state such as contact of a sample container containing a sample. For example, the temperature device is applicable to a nucleic acid amplification apparatus with a sample as a biological sample, and genetic testing equipment having the nucleic acid amplification apparatus installed therein. The principle of nucleic acid amplification is also applicable to Loop-mediated isothermal amplification (LAMP).

### REFERENCE SIGNS LIST

1 temperature control device
2 nucleic acid amplification apparatus
11 computation unit
12 control unit
13 display unit
14 storage unit
15, 16 thermal network model
17 temperature control unit
18 carrying device
101 sample
102 sample container
103 sample container holder
104 holder temperature sensor
105 temperature control element
106 casing
107 in-casing temperature sensor
108 apparatus main body

1. A temperature control device comprising:
a sample container holder configured to hold a sample container;
a plurality of temperature sensors configured to measure a temperature near a sample contained in the sample container;
a temperature control element configured to heat or cool the sample container holder;
a storage unit configured to store a mathematical model; and
a computation unit configured to analyze the mathematical model, based on an output from each of the plurality of temperature sensors,
wherein the mathematical model serves as a thermal network model in which nodes and a thermal resistance between predetermined nodes are set, the nodes corresponding at least to the sample, the sample container, the sample container holder, the plurality of temperature sensors, and the temperature control element, each node having a predetermined heat capacity, and
the computation unit uses a state estimation algorithm to calculate a thermal resistance estimated value between the sample container and the sample container holder and a temperature estimated value of the sample, based on the output from each of the plurality of temperature sensors and the thermal network model.

2. The temperature control device according to claim 1, further comprising:
a control unit configured to control a value of current to be supplied to the temperature control element,
wherein the control unit controls the value of current to be supplied to the temperature control element, based on the temperature estimation value calculated by the computation unit.

3. The temperature control device according to claim 2,
wherein the state estimation algorithm serves as a state estimation algorithm that employs any of a Kalman filter, an extended Kalman filter, an unscented Kalman filter, an ensemble Kalman filter, and a particle filter.

4. The temperature control device according to claim 3, further comprising:
a casing containing the sample container holder, the plurality of temperature sensors, and the temperature control element; and
a holder temperature sensor configured to measure a temperature of the sample container holder and an in-casing temperature sensor configured to measure a temperature of an in-casing air, as the plurality of temperature sensors,
wherein the mathematical model serves as a thermal network model in which nodes and a thermal resistance between predetermined nodes are set, the nodes corresponding at least to the sample, the sample container, the sample container holder, the holder temperature sensor, the in-casing temperature sensor, the temperature control element, the casing, the in-casing air, each node having a predetermined heat capacity.

5. The temperature control device according to claim 4, further comprising:
a display unit configured to display a cautionary notice in a case where an analysis result of the computation unit is significantly different from a desired temperature transition.

6. The temperature control device according to claim 5,
wherein the display unit determines, based on the thermal resistance estimated value, an abnormality of disposition of the sample container in the sample container holder, to display a cautionary notice.

7. A nucleic acid amplification apparatus comprising:
a plurality of the temperature control devices according to claim 1.

8. The nucleic acid amplification apparatus according to claim 7,
wherein nucleic acid amplification treatment is performed by a polymerase chain reaction method.

9. The nucleic acid amplification apparatus according to claim 7, further comprising:
a carrying device configured to dispose the sample container in the sample container holder,
wherein the carrying device determines, based on the thermal resistance estimated value, an abnormality of disposition of the sample container in the sample container holder, and re-disposes, in a case of determining presence of the abnormality, the sample container in the sample container holder.
